(19) United States
(12) Patent Application Publication
(10) Pub. No.: US 2009/0256259 A1
(43) Pub. Date: Oct. 15, 2009

(54) SEMICONDUCTOR DEVICE AND METHOD FOR MANUFACTURING THE SAME

(75) Inventor: Hiroyuki KANAYA, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/392,052

(22) Filed: Feb. 24, 2009

(30) Foreign Application Priority Data
Apr. 14, 2008 (JP) 2008-104667

(51) Int. Cl. H01L 23/48; H01L 21/768

(52) U.S. Cl. 257/751; 438/3; 438/627; 257/295; 257/E23.16; 257/E21.584

(57) ABSTRACT

A semiconductor device has a first interlayer insulating film formed on a semiconductor substrate, a first plug and a second plug embedded in holes formed to open the first interlayer insulating film, a capacitor formed on the first interlayer insulating film so as to connect to the first plug, a hydrogen barrier film including an aluminum oxynitride material and formed so as to cover the capacitor, the first interlayer insulating film and the second plug, a second interlayer insulating film formed on the hydrogen barrier film, a third plug embedded in a hole formed so as to open the second interlayer insulating film and the hydrogen barrier film and expose an upper surface of the upper electrode, and a fourth plug embedded in a hole formed so as to open the second interlayer insulating film and the hydrogen barrier film and expose an upper surface of the second plug.

### CROSS REFERENCE TO RELATED APPLICATION

This application is based upon and claims benefit of priority from the Japanese Patent Application No. 2008-104667, filed on Apr. 14, 2008, the entire contents of which are incorporated herein by reference.

### BACKGROUND OF THE INVENTION

The invention relates to a semiconductor device and a method for manufacturing the same.

FeRAM (Ferroelectric Random Access Memory) is non-volatile memory which employs a ferroelectric film such as PZT (Pb(ZrₓTi₁₋ₓ)O₃), BIT (Bi₄Ti₃O₁₂) or SBT (SrBi₂Ta₂O₉) in capacitor portions, and uses the residual polarization of the ferroelectric film to store data.

Since ferroelectrics such as PZT are oxides, when a gas which is mainly hydrogen penetrates, the ferroelectric is reduced and loses a degree of crystallinity. The result is deterioration in the ferroelectric properties. As capacitors have been miniaturized, the effect of hydrogen has increased. Since the manufacturing processes for the semiconductor device include a large amount of processing which takes place in an atmosphere including hydrogen, it is necessary to prevent hydrogen from penetrating into the ferroelectric film.

In order to solve such problems, FeRAM has been proposed in which the capacitors are covered with an alumina (Al₂O₃) film to prevent the penetration of hydrogen (see, for example, U.S. Pat. No. 7,029,925 and International Publication WO 2004/095578). By increasing the film thickness of the alumina film which covers the capacitors, it is possible to strengthen the protection against hydrogen damage.

However, when the alumina film which covers the capacitors is thick, there is a problem in that it becomes difficult to make openings for contact holes extending to the diffusion layers of switching transistors, contact holes extending to capacitor upper electrodes, and the like. As result, there is a drop in contact yield.

There is a further problem in that the large amount of oxygen included in the thick alumina film diffuses into a barrier metal film formed on an underside portion of the capacitor lower electrode, causing oxidation and peeling of the barrier metal film, and consequently, deterioration in the capacitor characteristics.

### SUMMARY OF THE INVENTION

According to one aspect of the present invention, there is provided a semiconductor device comprising:

a semiconductor substrate;

a first interlayer insulating film formed on the semiconductor substrate;

a first plug and a second plug embedded in holes in the first interlayer insulating film;

a capacitor including a conductive barrier film formed on the first interlayer insulating film so as to connect to the first plug, and, layered on the barrier film in the following order, a lower electrode, a ferroelectric film and an upper electrode;

a hydrogen barrier film including an aluminum oxynitride material on the capacitor, the first interlayer insulating film and the second plug;

a second interlayer insulating film formed on the hydrogen barrier film;

a third plug embedded in a hole through the second interlayer insulating film and the hydrogen barrier film exposing an upper surface of the upper electrode;

a fourth plug embedded in a hole through the second interlayer insulating film and the hydrogen barrier film exposing an upper surface of the second plug; and

a wiring layer formed on the second interlayer insulating film so as to connect to the third plug and the fourth plug.

According to one aspect of the present invention, there is provided a manufacturing method for a semiconductor device, comprising:

forming an interlayer insulating film on a semiconductor substrate;

forming a first hole and a second hole in the interlayer insulating film and expose a surface of the semiconductor substrate;

forming a first plug and a second plug by embedding a conducting film in the first hole and the second hole respectively;

forming a capacitor on the interlayer insulating film which connects to the first plug and includes a conductive barrier film, a lower electrode, a ferroelectric film and an upper electrode which form layers in the stated order; and

forming a hydrogen barrier film on the capacitor, the interlayer insulating film and the second plug, the hydrogen barrier film including an aluminum oxynitride material.

### BRIEF DESCRIPTION OF THE DRAWINGS

FIG. 1A is a cross-sectional view illustrating a manufacturing method for semiconductor device according to an embodiment of the invention;

FIG. 1B is a cross-sectional view illustrating a manufacturing method for semiconductor device according to an embodiment of the invention.;

FIG. 2A is a cross-sectional view showing a step subsequent to FIG. 1A;

FIG. 2B is a cross-sectional view showing a step subsequent to FIG. 1B;

FIG. 3A is a cross-sectional view showing a step subsequent to FIG. 2A;

FIG. 3B is a cross-sectional view showing a step subsequent to FIG. 2B;

FIG. 4A is a cross-sectional view showing a step subsequent to FIG. 3A;

FIG. 4B is a cross-sectional view showing a step subsequent to FIG. 3B;

FIG. 5A is a cross-sectional view showing a step subsequent to FIG. 4A;

FIG. 5B is a cross-sectional view showing a step subsequent to FIG. 4B;

FIG. 6A is a cross-sectional view illustrating a manufacturing method for a semiconductor device according to a comparative example;

FIG. 6B is a cross-sectional view illustrating a manufacturing method for a semiconductor device according to a comparative example;

FIG. 7A is a cross-sectional view showing a step subsequent to FIG. 6A;

FIG. 7B is a cross-sectional view showing a step subsequent to FIG. 6B;

FIG. 8 is a graph showing the relationships between a film thickness and capacitor polarizability when a damage blocking film is an AlON film and when the damage blocking film is an Al₂O₃ film;

FIG. 9 is a process cross-sectional view illustrating a manufacturing method for a semiconductor device according to a modification;

FIG. 10A is process cross-sectional view illustrating a manufacturing method for the semiconductor device according to the modification;

FIG. 10B is a graph showing a relationship between depth in the damage blocking film and nitrogen concentration;

FIG. 11A is a vertical cross-sectional view of the damage blocking film according to a modification; and

FIG. 11B is a vertical cross-sectional view of the damage blocking film according to a modification.

### DESCRIPTION OF THE EMBODIMENTS

Embodiments of the invention will now be described with reference to the drawings.

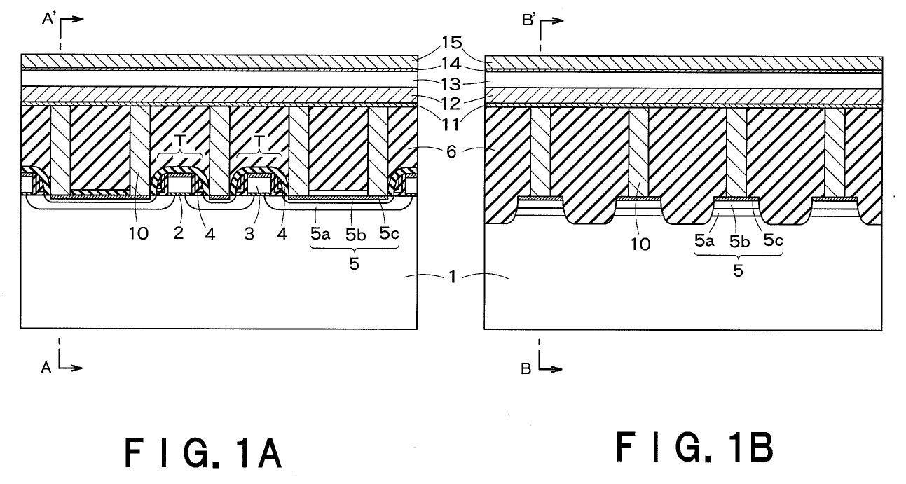

The manufacturing method for the semiconductor device according to the present embodiment of the invention is described with reference to the process cross-sectional views of FIGS. 1 to 5. In each of FIGS. 1 through 5, “A” is a vertical cross-section along a line perpendicular to a word line of a switching transistor, and “B” is a vertical cross-section along a word line.

As shown in FIGS. 1A and 1B, a transistor T is formed on a semiconductor substrate using well-known process. The transistor T is formed using a gate insulating film 2, a gate electrode 3 which is to become a word line, a gate cap film and gate side-wall film 4, and a source/drain diffusion layer 5.

The diffusion layer 5 has an LDD (Lightly Doped Drain) structure which includes a deep diffusion layer 5a, a shallow diffusion layer 5b, and a silicide layer 5c.

A silicon oxide film is then deposited using a CVD (Chemical Vapor Deposition) method and flattened using CMP (Chemical Mechanical Polishing) to form an interlayer insulating film 6.

Next, a plug 10, which connects an FeRAM capacitor portion, which is formed in a subsequent process, to an active area (source or drain) of the transistor T, is formed. The plug 10 is formed from tungsten. To form the plug 10, a blanket CVD method and CMP are combined.

Next, a TiAlN film 11, an Ir film 12, a PZT film 13, an SRO (SrRuO₃) film 14, and an IrO₂ film 15 are formed in the stated order on the interlayer insulating film 6 and the plug 10.

The TiAlN film 11 is, for instance, formed with a film thickness of 30 nm using a sputtering method. The Ir film 12 is, for instance, formed with a film thickness of 120 nm using a sputtering method. The TiAlN film 11 is a barrier metal film (conductive barrier film) and the Ir film 12 is a lower electrode film of the capacitor.

The PZT film 13 is, for instance, formed with a film thickness of 100 nm using a sputtering method. The PZT film may alternatively be formed using a CVD method at a temperature of 600° C.

The SRO film 14 is, for instance, formed with a film thickness of 10 nm using a sputtering method. The IrO₂ film 15 is, for instance, formed with a film thickness of 70 nm using a sputtering method. The SRO film 14 and the IrO₂ film 15 form an upper electrode film of the capacitor.

FIG. 1B is a cross-section taken along line A-A′ in FIG. 1A, and FIG. 1A is a cross-section taken along line B-B′ in FIG. 1B.

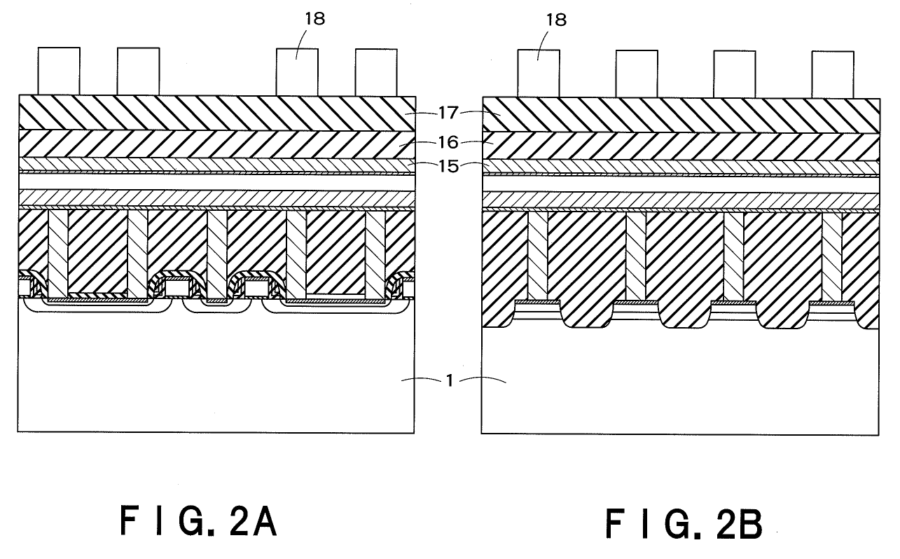

As shown in FIGS. 2A and 2B, an AlON film 16 with a film thickness of 100 nm and an SiO₂ film 17 with a film thickness of 500 nm are formed on the IrO₂film 15. Further, a resist 18 is formed on the SiO₂ film 17 and patterned into a mask for capacitor fabrication.

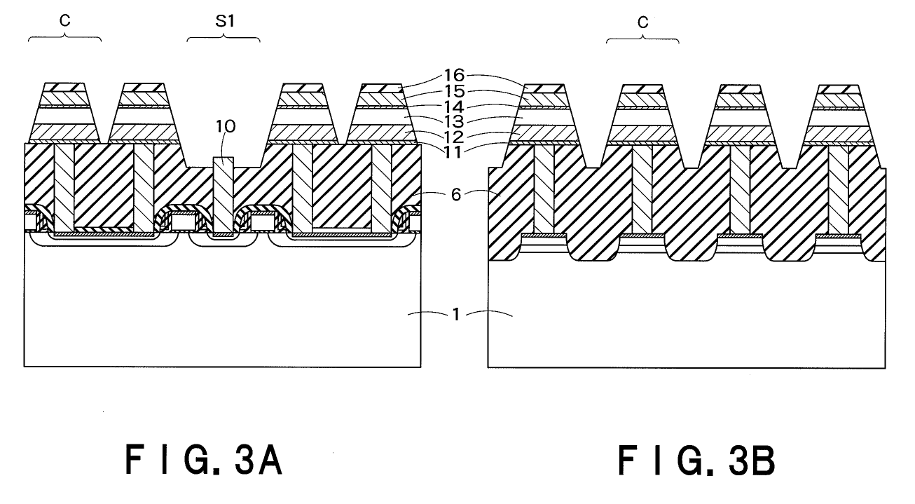

As shown in FIGS. 3A and 3B, with the resist 18 as a mask, RIE (Reactive Ion Etching) is performed to etch the SiO₂ film 17. After the resist 18 has been removed, the AlON film 16, the IrO₂ film 15, the SRO film 14, the PZT film 13, the Ir film 12 and the TiAlN film 11 are removed by RIE etching with the SiO₂ film 17 as a mask, in a processes to form the capacitor C.

The SiO₂ film 17 and the AlON film 16 act as a hard mask in the process to form the capacitors. The RIE used to etch the SiO₂ film is preferably room-temperature RIE. The RIE used to etch the AlON film is preferably high-temperature RIE at a temperature of 300° C. or more.

Note also that, in this process, in a region S1 which corresponds to a wide interval between capacitors (hard mask portions), the interlayer insulating film 6 and the plug 10 are partially removed and consequently an upper portion of the plug 10 is exposed.

After the capacitor fabrication, the hard mask (i.e. the SiO₂ film 17 and the AlON film 16) may be removed or allowed to remain. In the present embodiment, the SiO₂ film 17 is removed and the AlON film 16 is allowed to remain. The AlON film 16 is for suppressing hydrogen damage and the like to the PZT film 13 which can occur via the upper electrode film in a subsequent process.

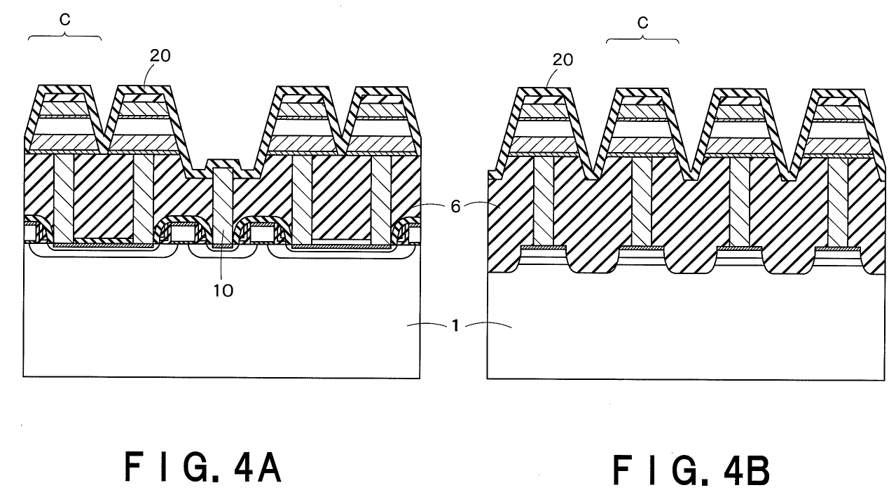

As shown in FIGS. 4A and 4B, an aluminum oxynitride film (AlOₓN_{y} film such as AlON film) 20 is formed with a film thickness of 50 nm by an ALD (Atomic Layer Deposition) method, so as to cover the capacitor C, the interlayer insulating film 6 and the plug 10. Note that, here, a plasma CVD method or sputtering method may be used instead of the ALD method. The aluminum oxynitride film 20 functions as a damage blocking film (hydrogen barrier film) for suppressing hydrogen damage and the like to the capacitor C in subsequent multilayer processes.

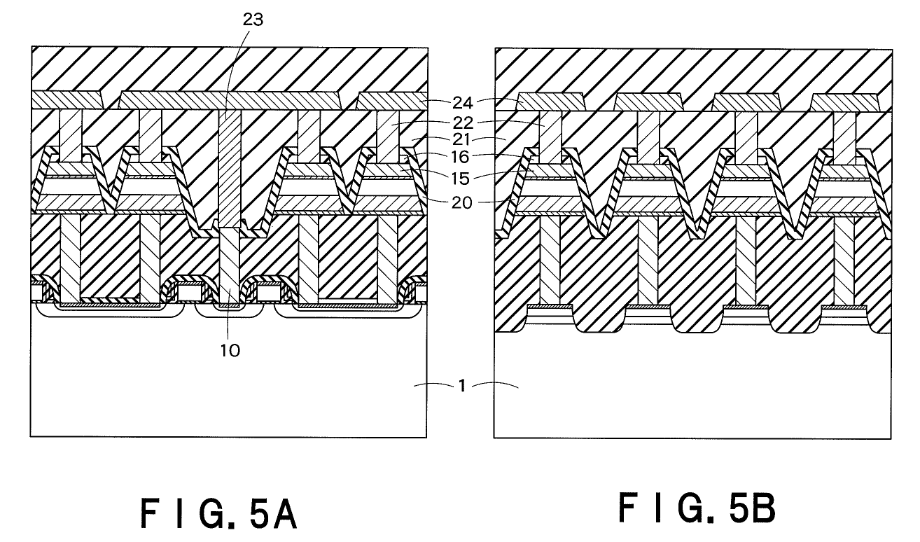

As shown in FIGS. 5A and 5B, a silicon oxide film is deposited on the AlON film 20 and flattened to form an interlayer insulating film 21. Next, predetermined regions of the interlayer insulating film 21, the aluminum oxynitride films 20 and 16 are removed to form contact holes which expose the upper surface of the IrO₂ film 15. Plugs 22 are formed by embedding aluminum in the contact holes.

Also, the interlayer insulating film 21 and the aluminum oxynitride film 20 are removed to form a contact hole so as to expose the upper surface of the plug 10. Plug 23 is formed by embedding tungsten in the contact hole. Metal wiring 24 connecting the plugs 22 and 23 is then formed.

### COMPARATIVE EXAMPLE

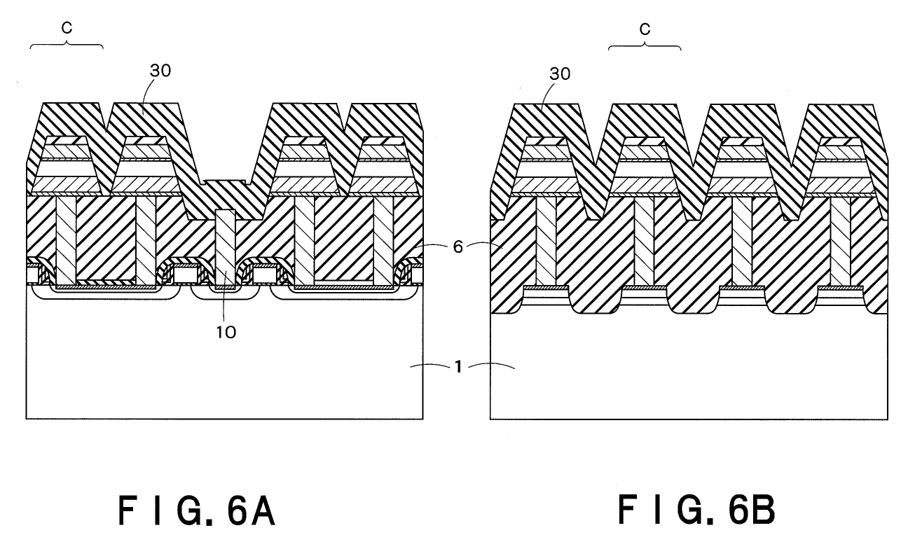

The following describes a manufacturing method for the semiconductor device according to a comparative example. Since the processes of the comparative example are similar to those of the above-described embodiment up to the process shown in FIGS. 3A and 3B, the description of these processes is omitted. As shown in FIGS. 6A and 6B, an Al₂O₃ film 30 is on the capacitor C, the interlayer insulating film 6 and the plug 10. The Al₂O₃ film 30 functions as a damage blocking film for suppressing hydrogen damage and the like to the capacitor C in subsequent multilayer processes. In order to obtain sufficient suppression of hydrogen damage and the like, the film thickness of the Al₂O₃ film 30 was set to 150 nm.

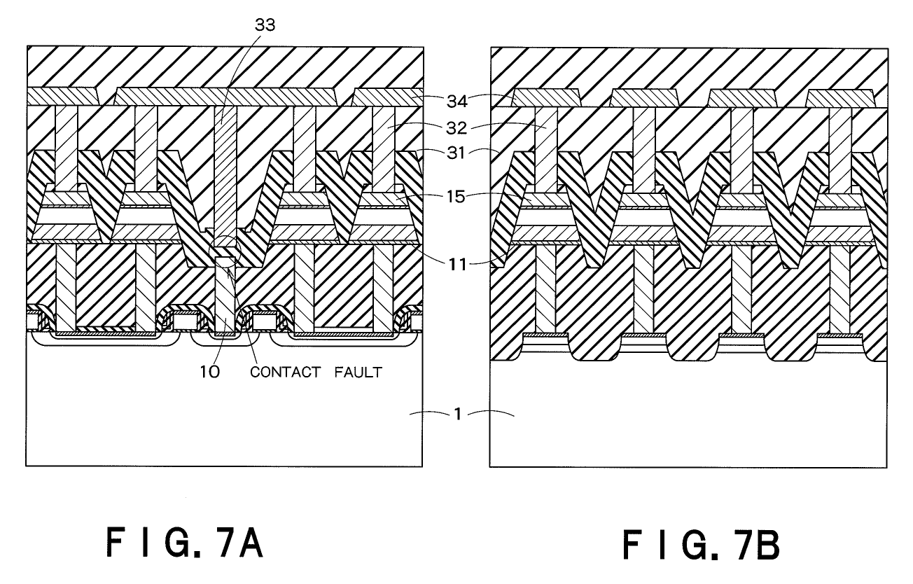

As shown in FIGS. 7A and 7B, a silicon oxide film is then deposited on the Al₂O₃ film 30 and flattened to form an interlayer insulating film 31. Plugs 32 contacting the IrO₂ film 15 and a plug 33 contacting the plug 10 are then formed. Metal wiring 34 or the like connecting the plugs 32 and 33 is then formed.

Here, because Al₂O₃ film 30 that is the damage blocking film has a thickness of 150 nm, it is difficult to form the contact holes. It is especially difficult to form the contact hole in which the plug 33 is to be formed. If the upper surface of the plug 10 can not be exposed, the plug 33 is unable to contact with the plug 10 in the manner shown in FIG. 7A, and the contact yield is reduced.

The degree of difficulty involved in forming the contact holes is dependent on the aspect ratio of the contact holes. The smaller the contact diameter with respect to the depth of the contact hole, the more difficult it is to form the contact hole. Specifically, it has been found that when the contact diameter is ¼ of the contact hole depth or less, there is a large drop in the contact yield for the plug 33.

This poses a greater problem in FeRAM having a structure in which units made up of a T and a C connected in parallel are connected in series in which a number of contact holes must be formed in a cell portion.

A further problem is that some of the large amount of oxygen included in the Al₂O₃ film 30 diffuses into the TiAlN film 11, causing oxidation and peeling of the TiAlN film 11 and consequently degrading the capacitor characteristics.

In the present embodiment, on the other hand, the aluminum oxynitride film is used as the damage blocking film 20 which covers the capacitor. Due to the inclusion of nitrogen, the aluminum oxynitride film offers greater suppression of hydrogen damage and the like than the Al₂O₃ film. Thus, for the same film thickness, the aluminum oxynitride film gives greater suppression of the hydrogen damage and the like than the Al₂O₃ film.

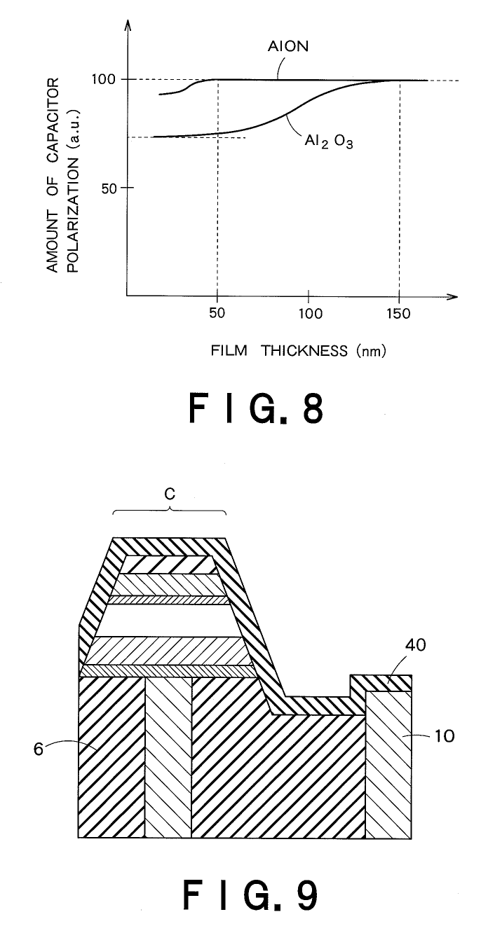

FIG. 8 shows an example of the relationships between the film thickness and an the amount of capacitor polarization in the case in which an AlON film is used as the damage blocking film which covers the capacitor and the case in which an Al₂O₃ film is used as the same. As is clear from the graph, an AlON film 20 having a film thickness of 50 nm, for example, provides the same degree of suppression of hydrogen damage and the like as is obtained when the damage blocking film was formed using the Al₂O₃ film 30 having a thickness of 150 nm in the comparative example.

Through use of the aluminum oxynitride film, the damage blocking film can be made thinner. Also, even if the opening diameter of the contact hole for forming the plug 23 is ¼ of the opening depth or less, it is still possible to form a contact hole that exposes an upper surface of the plug 10.

Thus, in the present embodiment, by using the aluminum oxynitride film as the damage blocking film covering the capacitor, the damage blocking film is made thinner. Hence, the contact holes for forming the plugs (specifically the plug 23) can be formed more easily and the contact yield can be improved. As a result, it is possible to improve the product yield.

Further, since the amount of oxygen contained in the aluminum oxynitride film with the thin film thickness is small, oxidation and peeling of the TiAlN film 11 are suppressed, and the capacitor characteristics can be improved.

Although in the above embodiment, the aluminum oxynitride film 20 with the film thickness of 50 nm as the damage blocking film was formed by the ALD method, the aluminum oxynitride film 20 with the film thickness of 50 nm may formed by forming 30 nm using a sputtering method and then forming the remaining 20 nm using an ALD method.

The ALD method offers good coverage, but is performed in a reductive atmosphere that includes hydrogen, and therefore introduces a small risk of damage to the PZT film 13. On the other hand, the sputtering method is capable of forming the aluminum oxynitride film without damaging the PZT film 13 but offers poor coverage.

Hence, the sputtering method is first used to form the aluminum oxynitride film without damaging the PZT film 13. Thereafter, with the aluminum oxynitride film formed by the sputtering method providing a block against the damage which can result from the ALD method, the ALD method is used to form an aluminum oxynitride film with good coverage. With this process, the capacitor characteristics are further improved and a highly reliable semiconductor device is obtained.

Alternatively, the damage blocking film may be given a layered structure made up of Al₂O₃ and aluminum oxynitride. The following describes a method for forming such a damage blocking film. Since the processes up to that shown in FIGS. 3A and 3B are similar to those of the above-described embodiment, further descriptions of these processes are omitted. The next step, as shown in FIGS. 9A and 9B, is to form an Al₂O₃ film 40 with a film thickness of 50 nm so as to cover the capacitor C, the interlayer insulating film 6 and the plug 10.

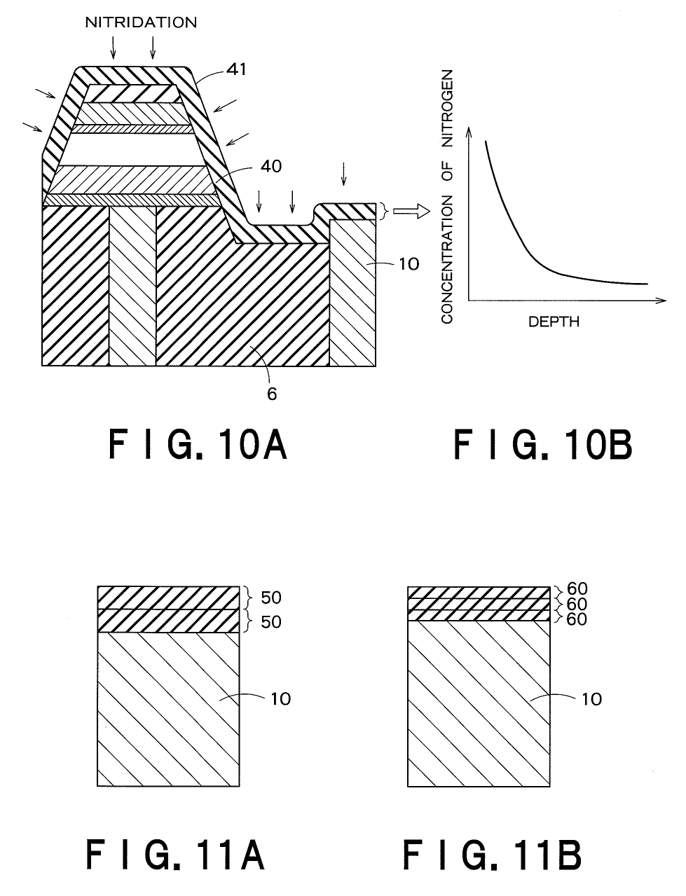

Then, as shown in FIG. 10A, a surface layer of the Al₂O₃ film 40 is nitrided by 3 minutes of nitridation in an N₂ plasma or N₂ atmosphere at 650° C. to form an aluminum oxynitride layer (such as an AlON layer) 41. At this point, the concentration of nitrogen included in the aluminum oxynitride layer 41 and the Al₂O₃ film 40 gradually reduces with depth from the surface, as shown in FIG. 10B.

Hence, with this type of multilayer Al₂O₃/aluminum oxynitride structure, it is still possible to obtain the same suppressive effects on hydrogen damage and the like as were obtained in the above-described embodiment using the aluminum oxynitride film 20. Further, since a specific sputtering apparatus is not required to form the aluminum oxynitride film, manufacturing costs can be reduced.

The Al₂O₃/Aluminum nitride multilayer structure may alternatively be formed by, for instance, forming an Al₂O₃ film with a film thickness of 30 nm and forming an aluminum oxynitride film with a film thickness of 20 nm on the Al₂O₃ film.

The damage blocking film may also have an Al₂O₃/aluminum oxynitride multilayer structure with an increased number of layers. For example, both formation of an Al₂O₃ film with a thickness of 20 nm and surface nitridation can be performed twice to provide two layers 50 of the multilayer Al₂O₃/aluminum oxynitride structure, as shown in FIG. 11A.

Alternatively, both formation of an Al₂O₃ film with a thickness of 10 nm and surface nitridation can be performed three times to provide three layers 60 of the Al₂O₃/aluminum oxynitride multilayer structure, as shown in FIG. 11B. Here, FIGS. 11A and 11B show only the damage blocking film formed on the plug 10.

A damage blocking film with a multilayer structure of this type also provides the same advantages as the above-described embodiment. Moreover, by increasing the number of layers it is possible to improve the damage suppressing effect, and as a consequence, to further reduce the overall thickness of the damage blocking film.

In the above-described embodiment, the multilayer structure of the AlON film 16 and the SiO₂ film 17 was employed as the hard mask in the capacitor fabrication. However, an Al₂O₃/SiO₂ structure may be used instead. The hard mask can have a multilayer structure including one or a combination of an aluminum oxynitride film (AlₓO_{y}N_{z} film such as AlON film), a silicon oxide film (SiOₓ film such as SiO₂film), an aluminum oxide film (AlₓO_{y} film such as Al₂O₃ film), a silicon aluminum oxide film (SiAlₓO_{y} film such as SiAlO film), a zirconium oxide film (ZrOₓ film such as ZrO₂ film), a silicon nitride film (SiₓN_{y} film such as Si₃N₄ film), and a titanium aluminum nitride film (TiAlₓN_{y} film such as TiAl_{0.5}N_{0.5} film).

What is claimed is:

1. A semiconductor device comprising:
a semiconductor substrate;
a first interlayer insulating film formed on the semiconductor substrate;
a first plug and a second plug embedded in holes in the first interlayer insulating film;
a capacitor comprising a conductive barrier film formed on the first interlayer insulating film, configured to connect to the first plug, and, layered on the barrier film in the following order, a lower electrode, a ferroelectric film and an upper electrode;
a hydrogen barrier film comprising an aluminum oxynitride layer on the capacitor, the first interlayer insulating film and the second plug;
a second interlayer insulating film formed on the hydrogen barrier film;
a third plug embedded in a hole through the second interlayer insulating film and the hydrogen barrier film exposing an upper surface of the upper electrode;
a fourth plug embedded in a hole through the second interlayer insulating film and the hydrogen barrier film exposing an upper surface of the second plug; and
a wiring layer formed on the second interlayer insulating film and configured to connect to the third plug and the fourth plug.

2. The semiconductor device of claim 1, wherein
the hole through the second interlayer insulating film and the hydrogen barrier film, exposing the upper surface of the second plug, is filled with the fourth plug of a diameter equal to or shorter than ¼ of a depth of the hole.

3. The semiconductor device of claim 1, wherein the hydrogen barrier film comprises:
an Al₂O₃ film; and
an aluminum oxynitride film formed on the Al₂O₃ film.

4. The semiconductor device of claim 1, wherein
a surface portion of the hydrogen barrier film is an aluminum oxynitride material.

5. The semiconductor device of claim 4, wherein
the hydrogen barrier film further comprises a second film formed on the aluminum oxynitride material and comprises a second aluminum oxynitride material at a surface portion.

6. The semiconductor device of claim 5, wherein
the hydrogen barrier film further comprises a third film formed on the second film and comprises a third aluminum oxynitride material at a surface portion.

7. A manufacturing method for a semiconductor device, comprising:
forming an interlayer insulating film on a semiconductor substrate;
forming a first hole and a second hole in the interlayer insulating film exposing a surface of the semiconductor substrate;
forming a first plug and a second plug by embedding a conducting film in the first hole and the second hole respectively;
forming a capacitor on the interlayer insulating film, configured to connect to the first plug and comprising a conductive barrier film, a lower electrode, a ferroelectric film and an upper electrode configured to form layers in the stated order; and
forming a hydrogen barrier film on the capacitor, the interlayer insulating film and the second plug, the hydrogen barrier film comprising an aluminum oxynitride material.

8. The manufacturing method for the semiconductor device of claim 7, wherein the hydrogen barrier film is formed by:
forming a first aluminum oxynitride film on the capacitor, the interlayer insulating film, and the second plug by a sputtering method; and
forming a second aluminum oxynitride film on the first aluminum oxynitride film by an ALD method.

9. The manufacturing method for the semiconductor device of claim 7, wherein the hydrogen barrier film is formed by:
forming an Al₂O₃ film on the capacitor, the interlayer insulating film and the second plug and
performing nitridation on a surface portion of the Al₂O₃ film in order to form a aluminum oxynitride material.

10. The manufacturing method for the semiconductor device of claim 7, wherein the hydrogen barrier film is formed by:
forming a first Al₂O₃ film on the capacitor, the interlayer insulating film and the second plug;
performing nitridation on a surface portion of the first Al₂O₃ film in order to form a first aluminum oxynitride material;
forming a second Al₂O₃ film on the first aluminum oxynitride material; and
performing nitridation on a surface portion of the second Al₂O₃ film in order to form a second aluminum oxynitride material.

11. The manufacturing method for the semiconductor device of claim 10, wherein the hydrogen barrier film is formed by:
further forming a third Al₂O₃ film on the second aluminum oxynitride material; and
performing nitridation on a surface portion of the third Al₂O₃ film in order to form a third aluminum oxynitride material.

12. The manufacturing method for the semiconductor device of claim 7, wherein the hydrogen barrier film is formed by:
forming an Al₂O₃ film on the capacitor, the interlayer insulating film and the second plug; and
forming an aluminum oxynitride film on the Al₂O₃ film.

13. The manufacturing method for the semiconductor device of claim 7, further comprising:
forming a second interlayer insulating film on the hydrogen barrier film;
forming a third hole through the second interlayer insulating film and the hydrogen barrier film exposing an upper surface of the upper electrode;
forming a third plug by embedding a conducting film in the third hole;
forming a fourth hole through the second interlayer insulating film and the hydrogen barrier film exposing an upper surface of the second plug;
forming a fourth plug by embedding a conducting film in the fourth hole; and
forming wiring layer on the second interlayer insulating film, configured to connect between the third plug and the fourth plug.

14. The manufacturing method for the semiconductor device of claim 13, wherein a diameter of the fourth hole is equal to or shorter than ¼ of a depth of the fourth hole.
